(19) United States
(12) Patent Application Publication
(10) Pub. No.: US 2026/0254185 A1
(43) Pub. Date: Aug. 27, 2026

(54) A DEVICE AND METHOD FOR RESONANT PUMPING OF OPTICAL GAIN MEDIUM IN A MANNER ORTHOGONAL TO A LASER MODE

(71) Applicant: RAMOT AT TEL-AVIV UNIVERSITY LTD., Tel Aviv (IL)

(72) Inventor: Tal CARMON, Haifa (IL)

(21) Appl. No.: 19/489,743

(22) PCT Filed: Jun. 5, 2024
(86) PCT No.: PCT/IB2024/055499

§ 371 Date: Dec. 3, 2025

Related U.S. Application Data
(60) Provisional application No. 63/471,021, filed on Jun. 5, 2023.

(51) Int. Cl. H01S 3/032; H01S 3/06; H01S 3/0933; H01S 3/16; H01S 3/17; H01S 3/22

(52) U.S. Cl. CPC H01S 3/0323; H01S 3/0625; H01S 3/0627; H01S 3/0933; H01S 3/1608; H01S 3/176; H01S 3/2207

(57) ABSTRACT

A device and method for resonant pumping of optical gain medium, comprising an electrical pump, an ultracoherent microlaser, and a plasma microresonator. The ultracoherent microlaser can comprise an orthogonal laser supported by a whispering-gallery disk resonator. The electrical pump can electrically pump plasma to trigger a semiconductor laser with 1 centimeter coherence to orthogonally resonantly enhance an ultracoherent laser. For a disk thickness near 1 micron, a factor of 20,000× in resonantly enhancing pump efficiency is achievable. The plasma microresonator can also comprise microbubble cavities, argon plasma, and walls thinner than an optical wavelength.

### CROSS-REFERENCE TO RELATED APPLICATIONS

This application is a National Phase entry under § 371 of International Application No. PCT/IB2024/055499, which claims priority to U.S. Provisional Patent Application No. 63/471,021, filed Jun. 5, 2023, each of which is hereby incorporated by reference in its entirety.

### FIELD OF THE DISCLOSURE

The present disclosure relates to the field of micro-lasers and specifically on-chip micro-lasers.

### BACKGROUND

### State-of-the-Art in Ultra-Coherent Lasers

In the general context of laser formation, the fundamental requirements involve two essential functions: gain and feedback. These functions can be fulfilled either by a single device providing both gain and feedback or, as an alternative, by employing two separate devices situated at different locations and optically coupled. In the latter method, one device provides gain, while the other provides feedback, give or take. Consequently, these distinctive arrangements are commonly referred to as the ‘internal cavity’ and ‘external cavity’ configurations. Current-lasers-technology can be divided based on their internal/external configuration as well as the specific type of gain medium employed. Below a few examples of each type of laser are provided. Notably, what follows is not a chronological and comprehensive review of the field of ultra-coherent lasers; but an aid to distinguish the present disclosure from current technology.

The different types of ultra-coherent lasers include:

1. Rare Earth internal cavity lasers (FIG. 1a-b). The fabrication of Rare Earth internal cavity lasers involves creating a resonator from a substrate that can provide both optical gain and support optical resonance. An excellent example of such a material is erbium-doped silica glass, which was developed to construct a toroidal on-chip laser. While Erbium enables a straightforward scalable internal-cavity configuration, it, unfortunately, does not permit easy electrical pumping schemes like semiconductors do.

Instead, on-chip Erbium lasers nowadays require optical pumping from another light source, which the present disclosure proposes to change. Optically pumping a micro-ring resonator poses a challenge. For instance, in FIG. 1, side illumination of the ring for optically pumping the Erbium only allows light to pass through 1 micron of the optical mode transverse cross-section. In contrast, the pump light must travel more than 10 meters through the erbium material to achieve population inversion. Such a long distance is only feasible through resonant pumping at a pump mode parallel to the laser mode and by using an external cavity laser of high coherency. An example of such a tabletop external cavity laser is depicted in FIG. 3c. While increasing the erbium concentration might enable non-resonant side pumping, this higher concentration also leads to increased material absorption, reducing the optical quality of the resonator and the coherency of the laser. Erbium-doped on-chip laser trades off coherency for a cumbersome pumping scheme relying on an ultra-coherent laser. It is worth mentioning that the Raman gain of silica glass, per se, can similarly be used in forming internal cavity lasers by using a spherical or toroidal dielectric microcavity. Similar to the erbium laser, though, another ultra-coherent laser is needed to resonantly pump these Raman lasers. At the end, one ultra-coherent laser is created while requiring another one (FIG. 1c) to pump it. This Erbium doped on-chip laser can be revisited in the objective sections of this proposal (a2.1 and FIG. 5a), where the present disclosure proposes to solve the pumping challenge while relying on a vertical Fabry-Perot and a cheap centimeter scale pump laser at 980 nm.

2. External cavity semiconductor lasers (FIG. 2) are created by separating the cavity and gain medium into distinct locations. An impressive illustration of an external cavity laser is the ultralow-noise miniature semiconductor laser (FIG. 2). Semiconductor lasers, in general, have been widely utilized as high-coherency emitters while compensating for the inherent lower coherency of laser diodes by employing various types of external cavities. Examples include whispering gallery mode resonators (FIG. 2) or mirror resonators (FIG. 1c). Alternative approaches to enhancing the coherency of semiconductor lasers involve distributed feedback reflectors, silicon nitride resonators, and silicon nitride on a sapphire photonic platform. Generally speaking, such methods facilitate the back-injection of light, into the semiconductor material. All of these methods rely on coupling, combining, or bonding between a device external to the semiconductor. In conclusion, a significant challenge in turning a semiconductor laser into emitters of ultra-coherent light arises from their relatively high absorption characteristics, which necessitate their coupling to an external resonator.

3. Internal-cavity semiconductor laser (FIG. 3b). Semiconductor-based internal cavity lasers, in their simplest realization, provide limited coherence. In detail, the currently accepted design of the semiconductor laser has been in use since the early 1970s but cannot achieve high coherence due to a fundamental issue originating from the relationship between induced emission (gain) and spontaneous emission (noise) dictated by quantum mechanics. This problem is further amplified by the concentration of optical energy in the high-loss III-V material. This can be mitigated through high absorption of the semiconductor by introducing a design approach that significantly reduces the spectral linewidth of the semiconductor laser compared to existing commercial lasers. The key distinction between the traditional semiconductor laser (FIG. 3a) and prior semiconductor laser (FIG. 3b) lies in a transfer of stored optical energy, typically 99%, from the III-V material to a nearly transparent high-index silicon material integrated into the laser resonator. Relevantly, a laser has been demonstrated where the gain medium overlaps with only 1% of the mode volume. As shown in FIG. 3b, the current disclosure proposes in the following sections a laser where plasma gain overlaps with 4% of the optical mode. Likewise, the presently disclosed gain medium has a lower index when compared with the nearby silica. Importantly, silica can potentially increase plasma coherency as shown in the present disclosure, in a similar manner to the way semiconductor coherency was improved (FIG. 3b)

4. Internal cavity plasma lasers. Just like semiconductors (and unlike Erbium), plasma is highly attractive since it converts electrical current to optical gain. Plasma benefits from being much more transparent than semiconductors and thus attractive to support ultra-coherent emitters. According to the present disclosure, plasma can provide the optical gain required for converting ultrahigh-Q on-chip resonators into functional electrically pumped ultra-coherent lasers.

The concept of large-scale plasma-based lasers has been recognized and studied since as early as 1963, marking its long-standing presence in laser research. However, these plasma-based lasers have never been successfully miniaturized to the micron scale. Lasers utilizing gases such as Argon, Xenon, and a mixture of Helium-Neon can be electrically pumped, similar to semiconductor lasers. The noble gases employed in these lasers belong to a family of elements known for having a complete outer shell of valence electrons. Consequently, plasma-based gain possesses advantages over semiconductors, including immunity to aging and reduced sensitivity to temperature variations. Remarkably, ultra-coherent plasma lasers can operate for several decades with minimal signs of aging or performance degradation, however, no one has yet downsized these lasers from their traditional benchtop scale to dimensions on the order of micrometers. One issue to be addressed is that there are materials that exhibit degradation when located near noble plasma. As for silica, as disclosed, it is considered durable to plasma. For example, the Brewster windows of argon laser tubes are made from silica glass and last longer than 8000 hours.

To summarize, FIG. 4 schematically presents 4 types of electrically pumped lasers. Relevantly here, plasma lasers are nowadays tabletop in size.

In non-optical applications, plasma was used for electrical switches responding within one picosecond. In meter-scaled experiments, plasma has supported ultra-coherent lasers as described supra, as well as fundamental studies in electron accelerators, and relativistic and nonlinear-optics.

### SUMMARY

### Plasma Micro-Photonics

The fast response speed of plasma can be useful for fast optical modulators, switches, and interconnects. The plasma-containing micro-resonator of the present disclosure, with electrically controlled optical refraction and absorption, is the only known implementation of plasma in micro-photonics. Objectives of the present disclosure include miniaturizing and integrating plasma lasers on-chip.

The presently disclosed plasma-containing resonator relies on microbubble cavities with walls thinner than an optical wavelength. The thin walls benefit in evanescently pushing the optical resonances to partially overlap with plasma. The present disclosure describes electrically ignited Argon plasma inside high-quality cavities and the measurement a refractive index reduction below one. Additionally, absorption-induced transmission was introduced, inverse to coherent-perfect-absorbers, by using plasma absorption to switch on the light in a cavity-coupled telecom-compatible fiber. The synergy between micro-photonics and plasma, which is shown below, enables new type of microcavities where resonantly enhanced light-plasma interaction occurs. Electrically controlling plasma to change its refraction might transform micro-cavities and electro-optical interconnects by adding additional knobs for electro-optically controlling light using currents, electric, and magnetic fields. Relevant to this disclosure, introducing active plasma at population inversion to microcavities permits a new type of electrically-pumped ultra-coherent micro-laser needed for many applications.

In detail, the disclosed electro-optical system includes plasma in the inner part of a microbubble resonator. The microbubble cavity resonantly enhances light when its circumference is an integer number of optical wavelengths. Crucially, a significant part of the resonance's mode-volume overlaps with the inner volume of the microbubble, where the plasma resides, enabling an electrical change of resonance properties by electrically ionizing argon gas to create plasma or inversely by a plasma recombination processes when electricity is off.

In all the micro-resonators that have been used to date, light propagates in solid, liquid, or gas media. In contrast, for the first time the present disclosure demonstrates a plasma-filled micro-resonator in which the optical resonance partially overlaps with the plasma. The design and fabrication of the disclosed microbubble resonator optimizes light extension into the plasma region. The resonator wall thickness is about 1 μm, achieved through pre-tapering a silica capillary, then heating using a CO₂ laser while controlling the applied inner air pressure. To further evanescently couple light into the inner plasma, a relatively large resonator radius of 90 μm is used, thus reducing the tendency of light to centrifugally move away from the inner plasma. Then, the microbubble cavity was filled with argon gas and copper micro-electrodes were inserted through both sides of the capillary. Sharp-tipped electrodes are used to enhance the local electric field to achieve gas breakdown. The continuous wave (CW) laser light was evanescently coupled to the bubble resonator through a tapered fiber coupler and its transmission was monitored by connecting the other side of the fiber coupler to a photodiode. Another photodiode sensitive to visible light is coupled through free space to monitor plasma luminescence. A spectrometer sensitive to visible and near IR was simultaneously used for plasma emission spectroscopy. Additionally, a visible camera was used for inspecting plasma luminescence and, simultaneously, an infrared (IR) camera was used for inspecting the IR resonance via its residual forward scattering. High-order TM bubble modes are preferred here since they better penetrate into the plasma. For example, the 5th-order polar mode has 4% of its mode volume overlapping with the plasma as numerically calculated using the method described herein.

The following experiments measure optical transmission through the cavity at different detuning while the plasma is ignited. Starting with theory, assuming Lorentzian absorption that characterizes resonators, the calculated optical transmission through the fiber as a function of plasma properties is:

$$T = 1 - \frac{4 ( {δ}_{c} ) ( {δ}_{0} + \text{?} )}{{( {δ}_{c} + {δ}_{0} + \text{?} )}^{2} + {( Δω + \text{?} )}^{2}} \qquad ( 1 )$$

c and δ_{c} represent the cavity coupling and loss rates, respectively, and Δω is the angular-frequency detuning between the laser and the cold cavity resonance. Plasma results in an additional cavity loss rate, [symbol] , and detuning, [symbol] , where the ~ stands for the time variation. The additional cavity loss rate, [symbol] , and detuning, [symbol] , are a function of plasma loss, αₚ, and refractive index, Δnₚ, which depends on the plasma properties. As evident from Equation 1, increasing plasma absorption, δₚ, increases the transmission through the cavity. Near critical coupling (δ_{c}=δ₀), transmission can rise from 0 to almost 1 as plasma absorption rises. In other words, while critically coupled, increasing the absorption of the cavity material reduces cavity absorption and consequently switches on the light emitted through the fiber. This absorption-induced transmission occurs since the higher optical loss is associated with a lower cavity quality factor that takes the fiber-coupled cavity to its under-coupled regime. While under-coupled, the effect of the resonator on the nearby fiber waveguide is negligible, so that the fiber turns almost transparent. As for changes in refractive index, they cause a drift in the resonance.

Absorption-induced transmission. The absorption-induced transmission was measured by tuning the laser wavelength to the cavity's optical resonance wavelength. The plasma pressure is 2.5 Torr. As shown, transmission rises from 5% to 78% upon breakdown and plasma formation. The optical rise time to half-max power is 100 ns, while plasma breakdown is characterized by a voltage rise time of ~20 ns for electrodes separated by 5 mm. It is noted that picosecond plasma rise times were possible when the distance between electrodes was closer.

Refractive index smaller than one. In contrast with absorption, the changes in the refractive index can result in opposite changes in transmission, depending on the detuning direction. When the laser wavelength is at the blue side of the resonance, plasma formation results in a narrow transmission dip followed by a peak and another dip. As shown and calculated in what follows, the first dip and peak could be the result of absorption, while changes in the refractive index could explain the dip that follows. This qualitative explanation is followed here by fitting the measured transmission to that of equation Eq. 1 while taking the plasma's absorption, αₚ, and refraction, Δnₚ, as free parameters. A best fit to the experimentally measured transmission was achieved with plasma absorption αₚ=3.68 cm⁻¹ and plasma refractive index of 0.999993 for a cavity Q of 2×10⁷. This refractive index corresponds c. In the fitting model described herein, plasma absorption and refraction are assumed to change with plasma density and plasma density is measured via its luminescence using a photodiode.

In conclusion, the present disclosure relates to the state of the art in micro-lasers and the efforts to compensate for semiconductor losses in multiple clever ways to achieve high coherency. All of these systems and methods are distinguished from the plasma-based solution-which can convert electricity to laser emission while exhibiting high transparency. Plasma was studied only in meter-scale lasers, and its introduction to on-chip photonics can open new research directions.

Additionally, the present disclosure also reviewed the state of the art in plasma-containing micro-resonators. Proof of feasibility experimentally showed resonantly enhanced light-plasma interactions where plasma absorption and refraction affect the cavity's transmission. Overall, the present disclosure addresses the need for affordable ultra-coherent emitters and the results prepare the ground for the next stage where plasma gain can be introduced, for the first time, to micro-photonics. Specifically, Erbium on-chip lasers, as discussed above, can be modified as disclosed in the following sections, to be electrically pumped.

Among other things, the present disclosure relates to the introduction of electrically pumped ultra-coherent emitters into chip technology, unlocking advanced communication and navigation capacities for daily life use and paving the way for on-chip plasma-based electro-optics.

Lasers such as erbium-based on-chip disk-lasers are nowadays challenging to pump. This is because current pumping technologies, among them resonantly pumping the laser parallel to the optical mode, limits the pump to have long coherence length (~10 meters), which is typically expensive.

This disclosure introduces perpendicular pumping of such disk lasers with a short coherence length source (~1 centimeter) which is typically cheap.

Some embodiments of the currently disclosed method rely on resonantly enhancing the relatively short-coherence pump along the axial direction of the disk, which is generally referred to as “vertical”. This can be done by activating the upper and lower faces of the disk to form a Fabry-Perot resonator.

As a non-limiting example, a disk 1 micron thick can accept only a small fraction of the light when simply vertically illuminated by a 1-centimeter coherency pump. Using a vertical resonator, as presently disclosed, a factor of 20,000 can be achieved in pump acceptance.

Coherence is the single most important parameter in affecting systems' precision. Chip-scaled ultra-coherent lasers can transform daily applications such as communication, navigation, and meteorology to benefit advanced capacities, previously available only in laboratories and defense applications.

Optical microcavities with ultrahigh quality factors have found applications in frequency combs, laser gyroscopes, sensors, atomic clocks, single-photon routers, LIDARs, optical synthesizers, cavity quantum electrodynamics, and optical RF oscillators for fast communication. Some of these systems occupied a large optical table on their first days and are used mostly in applications where cost is not an issue. Recently, these devices have been improving in size and mass-producibility as required for integration in daily life applications such as cellular phones, computers, routers, autonomous vehicles, and drones. Nevertheless, a crucial component for these high Q applications is still challenging. The crucial missing component is the affordable ultra-coherent micro-lasers as disclosed in the present disclosure.

Therefore, based on the foregoing and continuing description, the subject invention in its various embodiments may comprise one or more of the following features in any non-mutually-exclusive combination:
An electro-optical system for electrical pumping of plasma comprising an electrical pump comprising a cathode and an anode;
An electro-optical system for electrical pumping of plasma comprising a microbubble resonator comprising a silica capillary, the cathode and the anode disposed within the silica capillary;
An electro-optical system for electrical pumping of plasma comprising a microbubble cavity;
An electro-optical system for electrical pumping of plasma comprising a plasma disposed within the microbubble cavity;
An electro-optical system for electrical pumping of plasma wherein the cathode and anode are electrically coupled to the plasma to achieve lasing, thereby operating as a micro-laser;
An electro-optical system for electrical pumping of plasma wherein walls of the microbubble resonator are approximately 1 μm.

An electro-optical system for electrical pumping of plasma wherein the plasma is formed from a noble gas selected from the group consisting of Argon, Xenon, and a Helium-Neon mix.

An electro-optical system for electrical pumping of plasma wherein the plasma is formed from Argon.

An electro-optical system for electrical pumping of plasma wherein the gas disposed within the silica capillary is argon gas.

An electro-optical system for electrical pumping of plasma wherein a resonator wall of the microbubble resonator is approximately 1 μm;
An electro-optical system for electrical pumping of plasma wherein a radius of the microbubble resonator is approximately 90 μm;
An electro-optical system for electrical pumping of plasma wherein achievable optical resonances at least partially overlap with the plasma.

An electro-optical system for electrical pumping of plasma wherein the plasma is electrically pumped.

An electro-optical system for electrical pumping of plasma wherein the electrical pump is configured to generate a short coherence length pump light of approximately 1 centimeter.

An electro-optical system for electrical pumping of plasma wherein the plasma flows at a velocity of at least 1 cm/s through the microbubble cavity.

An electro-optical system for electrical pumping of plasma wherein the system is configured as an on-chip ultra-coherent plasma micro-laser (OUPML).

An electro-optical system for electrical pumping of plasma wherein lasing is achieved by applying a current of approximately 45 A in the presence of a longitudinal magnetic field of approximately 0.1 T.

An electro-optical system for electrical pumping of plasma comprising a long spiraling silica waveguide submerged in the plasma;

An electro-optical system for electrical pumping of plasma wherein the plasma flows at a velocity of at least 1 cm/s through the microbubble cavity;

An electro-optical system for electrical pumping of plasma wherein plasma absorption is approximately αp=3.68 cm⁻¹, plasma frequency is approximately ωp=4.55×10¹² Rad/s, and free-electron density is approximately ne~6×10¹⁵ cm⁻³.

An electro-optical system for electrical pumping of plasma wherein lasing is controlled by controlling an electrical current supplied to the cathode and anode.

An electro-optical system comprising an optoelectronic chip;
An electro-optical system comprising an micro-resonator comprising erbium gain medium;
An electro-optical system comprising a pump light source disposed to orthogonally pump the erbium gain medium to achieve lasing;
An electro-optical system wherein pumping is in a perpendicular vertical-direction to lasing.

An electro-optical system wherein the pump light source is another electro-optical system.

An electro-optical system comprising the pump light source, the pump light source comprising an electrical pump comprising a cathode and an anode, a microbubble resonator comprising a silica capillary, the cathode and the anode disposed within the silica capillary, a microbubble cavity, and a plasma disposed within the microbubble cavity, wherein the cathode and anode are electrically coupled to the plasma to achieve lasing, thereby operating 300 as a micro-laser.

An electro-optical system wherein the micro-resonator is an erbium-doped whispering gallery disk resonator.

An electro-optical system wherein an upper face and a lower face opposing the upper face of the erbium-doped whispering gallery disk resonator are coated with a reflective coating to achieve Fabry-Perot enhancement along the axial direction.

An electro-optical system wherein Fabry-Perot enhancement by a factor of approximately 20,000 is achieved.

An electro-optical system comprising a waveguide disposed near the micro-resonator to achieve optimal coupling.

An electro-optical system wherein a speed of light in the waveguide is equal to a speed of light in the resonator.

An electro-optical system wherein the waveguide is composed of silicon nitride.

An electro-optical system wherein the waveguide is a bent waveguide.

An electro-optical system wherein the pump light source is a laser emitting diode (LED) pump.

An electro-optical system wherein the LED pump comprises a 10 nm linewidth.

An electro-optical system wherein the pump light source is a semiconductor laser.

An electro-optical system wherein the semiconductor laser emits at 980 nm and is orthogonally resonantly enhanced along a vertical direction perpendicular to a whispering gallery mode to achieve azimuthal lasing at 1550 nm.

An electro-optical system wherein the pump light source has a coherence of approximately 1 cm.

An electro-optical system wherein lasing is emitted with coherence length of approximately 100-meters.

An electro-optical system wherein the system is a light detection and ranging (LIDAR) system.

### BRIEF DESCRIPTION OF THE FIGURES

FIG. 1. Internal cavity erbium laser in the form of erbium-doped silica ring. Green luminescence is the result of erbium up-conversion (from 1.5 to 0.5 micron) and is used here only to mark the location of the optical mode. (a) side view of the erbium-doped ring. (b) Top view. The top half of the micrograph was taken with the light off to present the location of the optical mode (green) relative to the ring. (c) An external cavity laser is needed to resonantly-pump the Erbium. A new focus velocity laser is shown here as a typical example of the laser needed to pump the laser in (a-b).

FIG. 2. External cavity semiconductor laser where the optical mode (a) is located in a micro-polished crystalline resonator (b). Rayleigh scattering from the resonator is back-injected into the semiconductor via a prism. In this method, the ultrahigh Q resonator (a, b) dictate the high coherency of the laser. Typical materials for the crystalline resonators include CaF₂ and MaF₂ and typical materials for the prisms include silicon and diamond.

FIG. 3. (a) The cross-sectional of a typical electrically driven semiconductor laser, accompanied by an illustration depicting the transverse profile of the electric field intensity. In this configuration, most of the light propagates at the semiconductor where absorption is high. (b) Deviating from the conventional semiconductor laser design, the laser mode is effectively drawn and guided by a closely positioned non-semiconducting layer adjacent to the active region. This layer possesses a low-loss characteristic, crucial for compensating the consequent reduction in modal gain. By positioning the active region within the evanescent tail of the mode, there is control over the optical-mode profile and, consequently, over the rate of spontaneous emission into the laser mode (dashed line and a solid line).

FIG. 4. Electrically pumped lasers. (a) Simple Internal cavity semiconductor laser exhibiting poor coherency. (b) External cavity semiconductor laser (c) Internal cavity semiconductor laser where mode is transversely pulled toward an ultra-transparent medium

FIG. 5. Perpendicular pumping of erbium whispering gallery mode laser where pumping at 980 nm is axial, and lasering at 1550 nm is azimuthal. (a) pumping with external illumination can allow resonantly enhancing the pump by a factor of 200 for LED illumination and 20,000 for semiconductor illumination. (b-c) integrating the LED/Semiconductor pump laser into the chip.

FIG. 6. Packaging mass producible ultra-coherent orthogonal micro-laser. Risk mitigation is by geometry (horizontal whispering gallery and vertical Fabry-Perot). In some embodiments free space coupling and waveguide coupling can be used.

FIG. 7. Orthogonal laser where the laser mode at 1550 nm (red) is an azimuthal mode supported by a whispering-gallery disk resonator. The pump is a standard semiconductor laser with 1 centimeter coherence that is orthogonally resonantly enhanced along the vertical direction. For disk thickness near 1 micron, a factor of 20000 is expected in resonantly enhancing pump efficiency, permitting for the first time an electrically pumped mass producible ultra-coherent laser.

FIG. 8. Packaging mass producible ultra-coherent lasers. Risk mitigation is by geometry (horizontal whispering gallery and vertical Fabry-Perot). In some embodiments free space coupling and wave guide coupling can be used.

FIG. 9. Schematic of an embodiment of the disclosed system.

FIG. 10. Schematic of an embodiment of the disclosed system.

### DETAILED DESCRIPTION

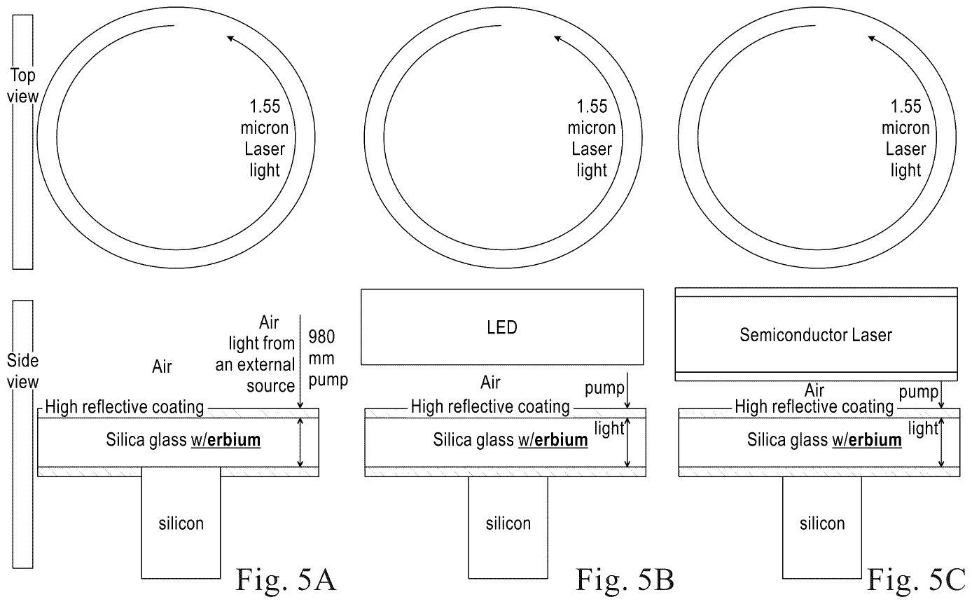

FIG. 5 describes an important objective of the present disclosure, namely, the demonstration of a mass-producible ultra-coherent emitter. Two efforts can be taken in parallel here to reduce risks. These ultra-coherent lasers can bridge the current technology gap where lasers trade-off coherency for mass producibility.

### Orthogonal Pumping of Erbium Laser on a Chip (FIG. 5)

The presently disclosed objectives include delivering an ultra-coherent mass-produced laser relying on a new way to resonantly pump Erbium using an integrated semiconductor laser. Vertical pumping can be done while benefiting from a Fabry-Perot enhancement along the axial direction, while lasering can be done horizontally at the azimuthal direction as nowadays common. The same on-chip erbium disk laser can be studied with 3 different pumping schemes. Starting from the simplest option and going mass production while changing one thing at a time as follows:

Step 1. External pump (FIG. 5a) at 980 nm, such as a microscope led or semiconductor illumination (e.g., by Navitar LTD) can be multiply reflected along the vertical direction of the disk resonator. Typical LEDs with 10 nm linewidth can offer a factor of 200 enhancement (Q=~2*980/10) where the factor of two stands for the fact that light goes forth and back (up and down) in each roundtrip. A laser diode coupled in the same manner can offer 20,000 enhancement assuming a silica thickness of 1 micron for the disk, as typical, and a semiconductor laser of 1-centimeter coherency

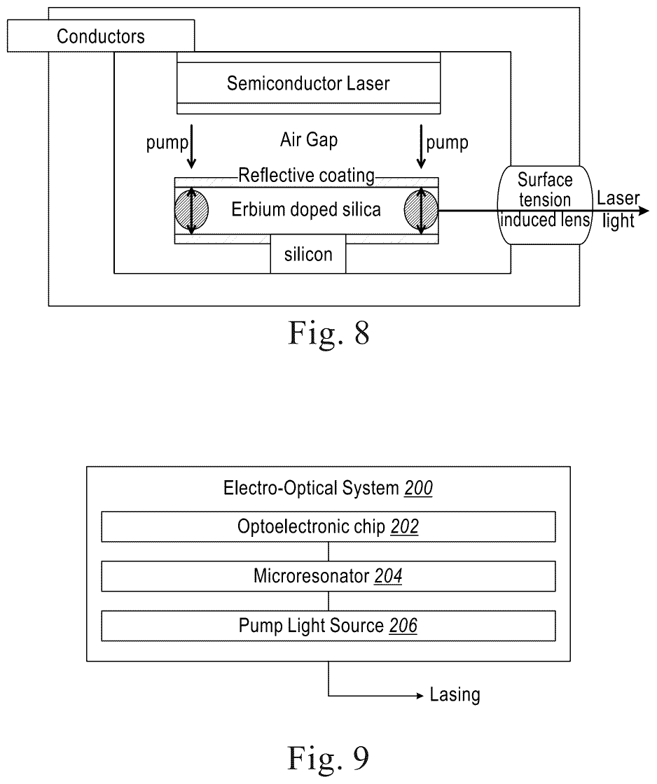

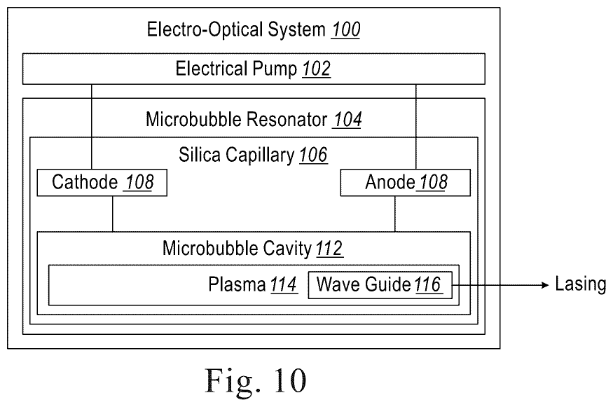

Step 2. Internal LED pump (FIG. 5b): same as above, while LED is integrated on a chip bound to the resonator chip. (FIG. 8b)

Step 3. Internal LED pump (FIG. 5c): same as above, but with a 980 nm laser.

### Demonstrating a Plasma Micro-Laser

This objective relates to the experimental demonstration of a plasma micro-laser in its most simplified manner so that risks can be minimal. In order to make the experiment as simple as possible, the optical coupling of the laser line out of the resonator can be done to free space via Rayleigh scattering and into a microscope objective. This is exemplified for observing micro-Raman laser, Third Harmonic Generation, and Brillouin laser. A two-dimensional parametric study can be performed to get the optimal plasma pressure and magnetic field that produce the maximal optical gain.

### Coupling the Lasers Through a Waveguide or a Lens

A waveguide such as the one made from silicon nitride can be fabricated near the silica resonator. A two-dimensional parametric study can be performed where the waveguide distance from the resonator and the waveguide thickness can be varied to achieve optimal coupling. Controlling the thickness of the waveguide can control the speed of light in this waveguide. The design criterion is to get the speed of light in the waveguide equal to the one in the resonator. This process is generally referred to as phase-matched coupling. The distance between the waveguide and the resonator determines coupling strength. The design criterion for coupling strength is optimal coupling, which is slightly weaker when compared to critical coupling and promises maximal laser output. Bent waveguides can be preferred to shorten the coupling distance and relax fabrication tolerances for phase matching requirements, as the applicant demonstrated experimentally in reference.

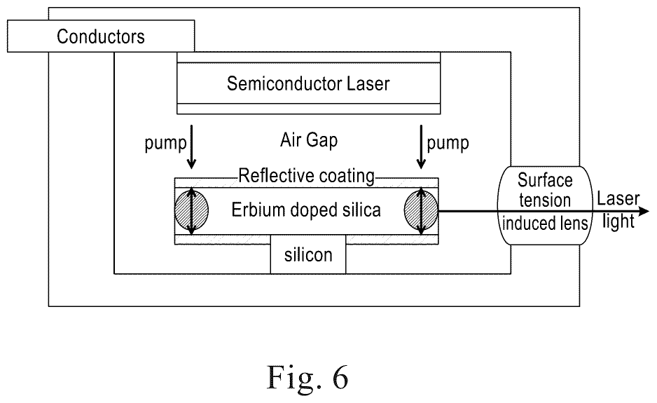

The disclosure also demonstrates a free space coupling mechanism that relies on light radiation while taking a sharp curve. A parametric study can be done while changing the bent radius to verify optimal coupling. To go fully on-chip, electrodes (FIG. 6) can be introduced to the chip to ignite plasma with them or turn the semiconductor pump on. In some embodiments, a vacuum cell on a chip is formed by bonding two separately fabricated chips with a void at the place where plasma resides. While vacuum cells on the chip were demonstrated, this task is most difficult and challenging. Full on-chip integration and packaging of ultra-coherent lasers, including optical couplers and conductors is also relevant.

### Methodology

The lab is equipped with laminar film-hoods, Xenon Difluoride etcher, and CO₂ lasers for fabricating and reflowing on chip resonators. Furthermore, the lab is equipped with seven optical tables, five of which are dedicated to this project. The laboratory has a continuous supply of clean nitrogen from an in-house generator. Similarly, Argon valves serve the relevant optical tables and vacuum cells in the lab. Additionally, two vacuum chambers were built for this project.

### Methodology for Demonstrating a Plasma Micro-Laser

For showing the first micro-plasma laser, two elements can be combined, and each one of them was shown separately to operate well:

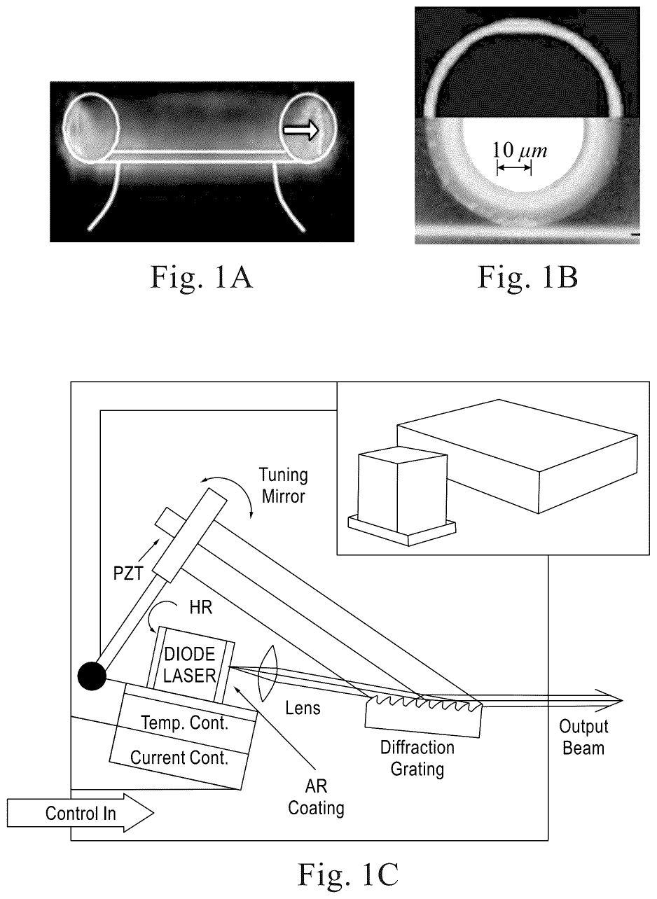

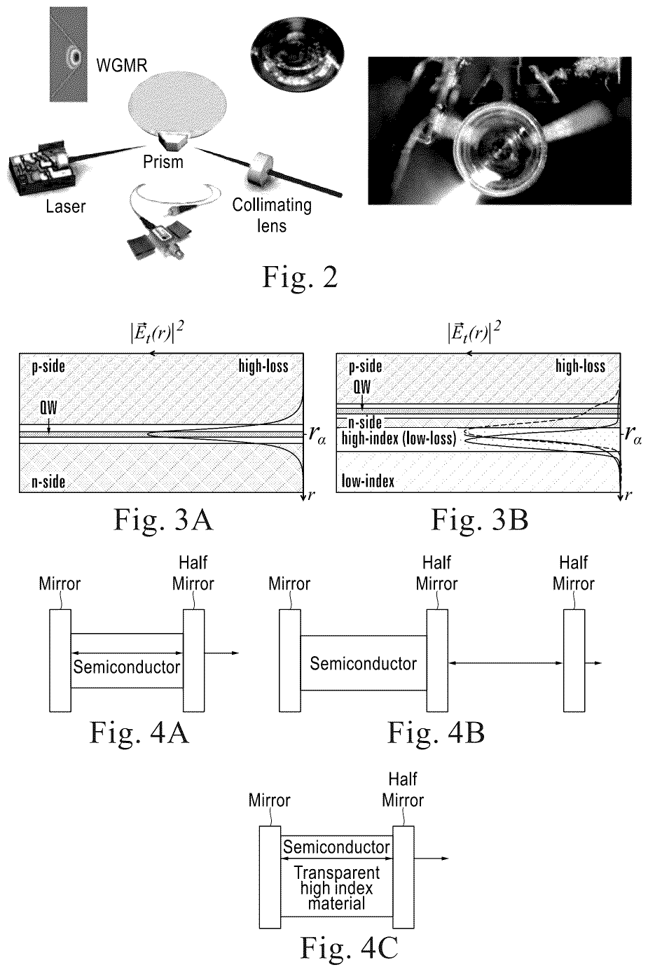

1) Ultrahigh Q micro-resonator. A variety of resonators can be used including (i) toroidal on chip resonators (FIG. 1, but with no erbium) (ii) spherical on chip resonators as the ones demonstrated, (iii) spherical whispering gallery resonators generated by melting the end of a standard telecom compatible fiber as demonstrated. Spherical resonators are exceptionally attractive, since their large number of transverse mode reduces the overall free spectral range (transverse and longitudinal) to be below arbong.

2) Plasma-containing vacuum cell.

### Methodology for Coupling the Plasma Laser to a Waveguide

Coupling can be improved to be optimal by:
parametrically changing the modal overlap via the waveguide-resonator distance;
parametrically scanning the speed of light in the waveguide via the waveguide width;
bending the waveguide to relax the fabrication tolerances required for phase matching as the applicant demonstrated in reference.

### Methodology for Orthogonal Laser

One wants to have 100-meter coherency for the ultra-coherent laser mode (which corresponds to an optical Q of 108 at 1550 nm. Using the current technology of parallel pumping requires an accordingly 100-meter coherency for the pump. In contrast, the presently disclosed orthogonal laser separates the variables of pumping and resonator to be orthogonal. Horizontally, the disk whispering gallery can be optimized to maximal coherency of the laser mode in addition to the optimal coupling of maximal energy to the user. Vertically, the top and bottom of the disk can be coated to become a Fabri-Perot resonator optimal for a 1-centimeter coherency semiconductor pump (corresponding to Q of 104 at 980 nm) in addition to an optimal coupling for well accepting the optical pump illuminating from above via free space.

### Risks and Mitigation

Except for the redundancy in trying to develop ultra-coherent lasers in two different ways, the disclosure addresses below the most difficult risk originating from the low power density of plasma.

Risk 1: Low power density of plasma is the major limitation in the possible output power of Argon micro-lasers. Approximately 8.5 W of power are typical to a 46 cm-long silica discharge tube with a 4-mm diameter. This was achieved by applying a current of 45 A (equivalent to 350 A cm⁻²) in the presence of a longitudinal magnetic field of 0.1 T. When going to micron cubed volumes, the potential power drops down.

Mitigation 1.1: plasma flow can compensate for its low power density by bringing fresh plasma toward the optical mode volume to provide sustainable gain. It can be encouraging that plasma velocities larger than km/s were reported. Yet, even a 1 cm/s speed can increase power by 10,000, assuming that the transverse cross-section of the relevant mode region is 1 micron.

Mitigation 1.2: A plasma-based amplifier can be added to the micro-laser. A long spiraling silica waveguide submerged in flowing plasma can address the relatively low gain of plasma. Notably, coherency is minimally modified while a weak laser power is amplified.

Coherency is a major figure of merit in optics, and the on-chip integration of ultra-coherent emitters could thus parallel the transformative shift witnessed from vacuum tubes to transistors.

### On-Chip Ultra-Coherent Plasma Micro-Laser (OUPML)

On-chip LiDARs, frequency combs, optical synthesizers, and gyroscopes with accuracy near that of large airborne devices are needed. A low-cost micro-laser with kilometer-scale coherence is crucial to make these laboratory experiments practical for applications such as cell phones and autonomous cars. Accordingly, an objective of the present disclosure is development of a new type of laser that is both low-cost and highly coherent. To achieve this, at least one embodiment of the invention utilizes noble-element plasma at the evanescent region of an on-chip resonator, harnessing its optical gain to create an ‘internal-cavity laser.’ This approach contrasts with current technology for ‘external-cavity lasers,’ where the low coherency of semiconductor (SC) diodes is compensated for through challenging coupling to an external cavity.

The presently disclosed laser might impact the field of ultra-coherent emitters to benefit everyday applications by providing advanced capabilities currently limited to large platforms where cost is not a constraint (e.g., radars). Synergizing between the seemingly unrelated disciplines of plasma and on-chip optics could achieve a transistor-type impact by introducing plasma as a complement to SC in optical micro-switches, modulators, and interconnects.

Risks, such as the relatively low optical gain of plasma, can be mitigated by a ‘safety net’ of developing on-chip mass-producible erbium lasers, where lasering is of an azimuthal whispering gallery type, yet pumping is in the perpendicular vertical-direction where reflective coatings permit resonant Fabry-Perot pump-enhancement by a factor of 20,000, using an integrated SC-laser pump.

The disclosed proof of feasibility includes the experimental demonstration of the first plasma-containing micro-resonators.

### Extended Synopsis

The present canonical design of the semiconductor laser (SCL), in force since the early 1970s, is incompatible with high coherence (narrow linewidth). The reason is fundamental and is a consequence of the quantum-mandated umbilical relationship between induced emission (gain) and spontaneous emission (noise) exacerbated by the modal concentration of optical energy in the high loss III-V material.

The present disclosure describes the design, fabrication, and demonstration of an on-chip micro-laser that is both ultra-coherent and mass-producible. Unlike current technologies, the disclosed micro-laser can utilize noble-element plasma to provide optical gain. Plasma is an ionized state of matter where an electrical field can produce optical gain. Integrating this gain into an on-chip resonator can produce laser emission using a single component that one can mass produced.

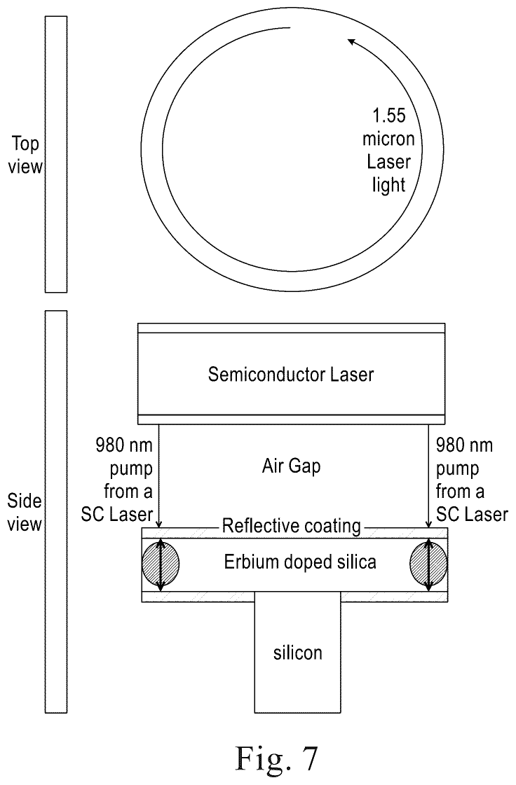

To mitigate risks, such as those relating to the vacuum cell that plasma requires, the present disclosure describes the development, in parallel, of another type of ultra-coherent laser that called an ‘orthogonal laser’ (FIG. 7). The orthogonal laser is based on a regular disk-shaped erbium laser emitting at 1550 nm. Yet, with a semiconductor pump laser, at 980 nm, that is resonantly enhanced vertically, perpendicular to the whispering gallery mode. Reflectors on the upper and lower faces of the cylinder can constitute a vertical Fabry-Perot serving this enhancement. A 1-centimeter coherency of the pump laser can permit 20,000 enhancement in pumping for a typical 1-micron thick disk; to turn it into an electrically pumped ultra-coherent laser. This is unlike the current state of the art, where a 100-meter coherency laser is needed to resonantly pump such disks through their whispering gallery mode. These lasers (FIG. 7) can be on-chip integrated with conductors and optical couplers and be commercialized.

The present disclosure demonstrates the first opto-electrical system comprising plasma-containing micro-resonator (for the plasma micro-laser), cheap high-power LEDs and laser diodes for pumping, as well as high-reflecting coatings (as needed for the orthogonal laser).

A current technological gap forces trading off ultra coherency for mass producibility. The present disclosure bridges this gap by introducing a plasma state-of-matter and orthogonal-resonance geometry (FIG. 7) to on-chip photonics. The disclosed affordable ultra-coherent lasers can transform recently demonstrated chip-scale LiDARs, gyroscopes, atomic clocks, frequency combs, etc., from the laboratory to daily life applications such as autonomous vehicles and cell phones.

### Scientific Objectives

The importance of developing a cost-effective ultra-coherent laser lies in its potential to enable advanced meteorology, navigation, and high-speed communication technologies into daily-life applications such as cell phones and autonomous vehicles. Currently, the high cost of ultra-coherent lasers restricts their usage primarily to markets such as those related to defense applications. Moreover, the broader impact of synergizing between micro-photonics and plasma (which were previously considered as belonging to unrelated disciplines) relates to the potential to revolutionize electro-optics by introducing an additional knob (plasma) to control light using currents, electric fields, and magnetic fields.

As described herein, plasma can become a standard electro-optic material in on-chip photonics, permitting electrically controlled light-plasma interactions. Below, the disclosure describes, in detail, potential applications followed by how ultra-coherent micro-lasers can turn such applications to benefit daily life. Optical microcavities with ultrahigh quality factors have found applications in frequency combs, laser gyroscopes, sensors, atomic clocks, single-photon routers, LIDARs, optical synthesizers, cavity quantum electrodynamics, and optical RF oscillators for fast communication. Some of these systems occupied a large optical table on their first days and are used mostly in applications where cost is not an issue. Recently, these devices have been improving in size and mass-producibility as required for integration in daily life applications such as cellular phones, computers, routers, autonomous vehicles, and drones. Nevertheless, a crucial component for these high Q applications is still challenging. The crucial missing component is the affordable ultra-coherent micro-lasers proposed here.

One example of the necessity of such a cheap long coherence source is Frequency-Modulated Continuous Wave (FMCW) LiDAR, where coherence supporting a 500-meter range can benefit a typical situation where two vehicles drive toward each other at a fast velocity. Such a 500-meter range LiDARs can cost more than a typical car, which is related mainly to the technology gap in mass-produced ultra-coherent lasers. The presently disclosed 560 mass-produced micro-lasers (FIG. 7) intend to bridge this gap, permitting the installation of several long-range LiDARs per car for viewing in different directions and overcoming blind spots. For example, LiDARs typically prefer the near IR eye safe light at the band where low cost CCDs are sensitive, for that—rare earth dopant other than Erbiums, and noble plasma other than Argon might be needed.

A primary motivation here relates to the ability of noble plasma to produce optical gain whilst staying highly transparent, which makes it suitable for ultra-coherent internal cavity micro-lasers. It might be encouraging that plasma lasers have been with us since 1963. Nevertheless, current plasma laser technology is tabletop and does not support mass-producibility. Until recently, plasma gain was insufficient to overcome microcavities' optical loss. The relatively low Q of micro-resonators made plasma micro-lasers that convert electrical current into ultra-coherent emission only a dream.

In 2003, toroidal resonators with an optical quality factor exceeding 400,000,000 were demonstrated at Caltech by Vahala's group. This breakthrough in cavity quality transformed them so that plasma gain is nowadays higher than the on-chip cavity loss. In detail, the calculations disclosed herein show that one can exceed the laser threshold by introducing plasma to the evanescent region around an on-chip resonator. In the calculations herein, the evanescent region surrounding a resonator occupies only a few percent of the mode volume as typical. The present disclosure differs from ultra-coherent on-chip micro-lasers relying on the gain of rare earth elements. In 2003, Lan Yang demonstrated on-chip micro-lasers with ultrahigh coherency by doping a toroidal resonator with erbium. Yang's work permitted on-chip lasers with kilometer-scale coherency. However, these on-chip micro-lasers require resonant pumping by another ultra-coherent laser, typically a tabletop external cavity diode laser, resulting in known problems regarding an affordable ultra-coherent emitter.

In the first disclosed laser, plasma is used as gain medium instead of Erbium. The second disclosed laser (FIG. 7) pumps in a direction orthogonal to the first laser, permitting resonantly enhancing a vertical 1 cm coherent pump with minimal effect on the horizontal laser mode.

Referring back to the plasma micro-laser disclosed herein, plasma is more transparent than semiconductors. Generally speaking, putting plasma between two mirrors can result in ultra-coherent light emission. On the contrary, a semiconductor laser per se can emit low coherency light because of the relatively low optical transmission of semiconductor materials. Current technology for achieving high coherency semiconductor lasers relies on coupling the semiconductor to an external cavity, increasing the number of components and requiring a challenging coupling between them. The present disclosure demonstrates on-chip gyroscopes, frequency combs, and optical synthesizers, among other applications, and surround their resonator with plasma, or activating them as in FIG. 7, unifying the functions of this very same resonator to also generate ultra-coherent light for itself.

The presently disclosed approach is to start from the micro-plasma laser where on-chip high Q resonators are put in a vacuum cell containing plasma at population inversion. Laser light can then be observed via residual scattering, which requires nothing except the resonator and surrounding plasma. Similarly, for the orthogonal laser (FIG. 7), at least one embodiment of the invention begins with an erbium-doped disk relying on standard sol-gel or ion implantation methods. Coating the upper and lower faces of the disk with materials not absorbing the laser light. Pumping can be first done with a thorough-the-lens illumination system for a microscope, where a 980 nm laser serves as the light source. Axicons can be added to turn the pump into a ring shape to improve mode overlap.

To conclude the first stage—the approach is to get an electrically pumped ultra-coherent laser. After that, packaging to the configuration appearing in FIG. 4 can be taken while trying to add only one thing at a time. The coupling can be by a waveguide such as the ones made from silicon nitride in many foundries and with lenses demonstrated through fluidic shaping. Coupling the resonator to free space can be done radiatively.

| | Feedback | Gain |
|---|---|---|
| Current | 1) Distributed Feedback | Semiconductor laser diode |
| technology | (DFB) resonator | |
| | 2) Micro-polished | Semiconductor laser diode |
| | crystalline resonator | |
| | 3) Silicon nitride resonator | Semiconductor laser diode |
| | chip | |
| Embodiments | 4) On-chip silica resonator | Plasma at population |
| of the present | | inversion on the very-same |
| invention | | chip. |
| | 6) Horizontal on-chip | Erbium resonantly pumped |
| | erbium-dopped resonator | by a vertical Fabry-Perot |
| | (whispering gallery) | |

Table 1: Ultra-coherent laser: (1-3) Current technology relies on coupling an external cavity that provides optical feedback to a semiconductor laser diode that provides optical gain. (4) The presently disclosed proposal for an internal-cavity laser where an on-chip resonator that provides feedback has plasma at part of its mode volume to provide gain.

Current technology in ultra-coherent lasers relies on several types of external cavities (Table 1, 1-3) coupled to the semiconductor laser diode. For example, bonding a silicon nitride resonator chip to a III-V semiconductor chip provides gain (Table 1, 3) for forming an external cavity laser. Efforts in bonding such silicon nitride resonators to III-Vs are currently conducted in several foundries with impressive progress. Along these lines, the technology of external-resonator lasers has exhibited a continuous and impressive trend of improvement over the past two decades. This research had emigrated from research labs to companies and foundries.

The present disclosure therefore crosses the disciplines of plasma science and micro-photonics by relying on novel orthogonal-resonator geometry. Unlike current technology, plasma is a non-solid state of matter where optical gain, absorption, and refraction are electrically controlled; however, it has never been considered for benefiting on-chip optics.

### Proof of Feasibility and Preliminary Experimental Result.

Described below is an experimental demonstration of the first plasma-containing micro-resonator. Crucially, the walls of the micro-resonators are thinner than an optical wavelength so that the optical resonance evanescently extends into the plasma region. Significant contributions to the development of such silica bubbles with walls thinner than wavelengths were by Chormaic. Resonantly enhanced light-plasma interaction was observed in the resonator described herein, where a refractive index lower than 1 was measured in the plasma regions. Plasma was then brought to population inversion to provide optical gain. With optical gain similar to what is reported in meter-scale Argon or Helium-Neon lasers—the presently disclosed calculation shows that a resonator with optical quality higher than 8×107 can be operating above the laser threshold.

Once, only light was resonating in microcavities. The applicant improved microcavities to hybridly host also resonances based on other waves in nature; among them, mechanical vibrations, water waves, and sound. To give just a few examples, the applicants optomechanical cavities permitted energy exchange between vibration and light, his opto-capillary cavities permitted water waves to mediate laser emission, and his optoacoustic cavities permitted the first micro-Brillouin laser as well as the first observation of Brillouin cooling. Brillouin cooling was theoretically suggested by Charles Townes, in his Brillouin-maser paper (1963), Eq. 9, and reported experimentally by the applicant half a century after. Relevantly here, the disclosure introduces new phases of matter to microcavities, including gas used for nano-flying photonics, cavity walls made of liquid that host water waves and plasm. In lasers, the disclosure demonstrated the first water-wave laser and the first micro Brillouin laser that was 100 μm in size (where the previous work was half a centimeter in size).

Coherence is the single most important parameter in affecting systems' precision. Chip-scaled ultra-coherent lasers can transform daily applications such as communication, navigation, and meteorology to benefit advanced capacities, previously available only in laboratories and defense applications.

All publications, patents, patent applications and other references cited in this application shall not be construed as an admission that such is prior art to the present invention.

The following is a summary of various reference numbers in the figures: 100 Electro-Optical System; 102 Electrical Pump; 104 Microbubble Resonator; 106 Silica Capillary; 108 Cathode; 110 Anode; 112 Microbubble Cavity; 114 Plasma; 116 Wave Guide; 200 Electro-Optical System; 202 Optoelectronic chip; 204 Micro-resonator; 206 Pump Light Source.

1. An electro-optical system for electrical pumping of plasma, comprising:
an electrical pump comprising a cathode and an anode;
a microbubble resonator comprising a silica capillary, the cathode and the anode disposed within the silica capillary;
a microbubble cavity for resonantly enhancing light, the microbubble cavity disposed within the microbubble resonator; and
a plasma disposed within the microbubble cavity;
wherein the cathode and the anode are electrically coupled to the plasma to achieve lasing, thereby operating as a micro-laser.

2. The electro-optical system of claim 1, wherein walls of the microbubble resonator are approximately 1 micrometer (μm) thick.

3. The electro-optical system of claim 1, wherein the plasma is formed from a noble gas selected from the group consisting of: argon, xenon, and a helium-neon mix, and wherein argon gas is disposed within the silica capillary.

4. (canceled)

5. (canceled)

6. The electro-optical system of claim 1, wherein:
a resonator wall of the microbubble resonator is approximately 1 micrometer (μm) thick, and
a radius of the microbubble resonator is approximately 90 μm.

7. (canceled)

8. The electro-optical system of claim 1, wherein
achievable optical resonances at least partially overlap with the plasma.

9. The electro-optical system of claim 1, wherein the plasma is pumped by an electrical pump, and wherein the electrical pump is configured to generate a short coherence length pump light of approximately 1 centimeter.

10. (canceled)

11. (canceled)

12. The electro-optical system of claim 1, wherein the system is configured as an on-chip ultra-coherent plasma micro-laser (OUPML).

13. The electro-optical system of claim 1, wherein the lasing is controlled by controlling an electrical current supplied to the cathode and the anode, the electrical current being approximately 45 amperes (A) in the presence of a longitudinal magnetic field of approximately 0.1 Tesla (T), wherein an absorption of the plasma is approximately 3.68 centimeters (cm)⁻¹, wherein a frequency of the plasma is approximately 4.55×10¹² rad per second, and a free-electron density is approximately 6×10¹⁵ cm⁻³.

14. The electro-optical system of claim 1, further comprising:
a long spiraling silica waveguide submerged in the plasma;
wherein the plasma flows at a velocity of at least 1 centimeter per second through the microbubble cavity.

15. (canceled)

16. (canceled)

17. An electro-optical system comprising:
an optoelectronic chip;
a micro-resonator comprising erbium gain medium; and
a pump light source disposed to orthogonally pump the erbium gain medium to achieve lasing;
wherein the pumping is in a perpendicular vertical-direction to the lasing.

18. The electro-optical system of claim 17, wherein the pump light source is the electro-optical system of claim 1.

19. The electro-optical system of claim 17, wherein the micro-resonator is an erbium-doped whispering gallery disk resonator having an upper face and a lower face opposing the upper face, and wherein the upper face and the lower face are coated with a reflective coating to achieve a Fabry-Perot enhancement of approximately 20,000 along an axial direction.

20. (canceled)

21. (canceled)

22. The electro-optical system of claim 17, further comprising:
a waveguide disposed near the micro-resonator to achieve optimal coupling.

23. The electro-optical system of claim 22, wherein a speed of light in the waveguide is equal to a speed of light in the micro-resonator.

24. The electro-optical system of claim 22, wherein the waveguide is (i) composed of silicon nitride, and/or (ii) a bent waveguide.

25. (canceled)

26. The electro-optical system of claim 17, wherein the pump light source is a laser emitting diode (LED) pump comprising a 10 nanometer (nm) linewidth.

27. (canceled)

28. The electro-optical system of claim 17, wherein the pump light source is a semiconductor laser configured to emit at approximately 980 nanometers (nm) and is orthogonally resonantly enhanced along a vertical direction perpendicular to a whispering gallery mode to achieve azimuthal lasting at approximately 1550 nm.

29. (canceled)

30. The electro-optical system of claim 17, wherein the pump light source has a coherence of approximately 1 centimeter (cm).

31. The electro-optical system of claim 17, wherein the lasing is emitted with a coherence length of approximately 100 meters.

32. The electro-optical system of claim 17, wherein the electro-optical system is a light detection and ranging (LIDAR) system.
